(19) United States
(12) Patent Application Publication
(10) Pub. No.: US 2026/0318966 A1
(43) Pub. Date: Oct. 15, 2026

(54) TEST DEVICE, TEST SYSTEM AND METHOD FOR TESTING A TEST OBJECT

(71) Applicant: Rohde & Schwarz GmbH & Co. KG, Munich (DE)

(72) Inventors: Thomas RUSTER, Munich (DE); Adam TANKIELUN, Ottobrunn (DE); Pontus SEGERBERG, Nacka (SE)

(21) Appl. No.: 19/578,948

(22) Filed: Mar. 26, 2026

(30) Foreign Application Priority Data
Apr. 10, 2025 (DE) 102025114111.8

(51) Int. Cl. G01R 29/08

(52) U.S. Cl. CPC G01R 29/0885

(57) ABSTRACT

A test device is proposed. The test device comprises a planar vapor cell which is filled with a gas, and a first light source configured to output a first light beam for exciting the gas to a Rydberg state. Furthermore, the test device comprises a second light source configured to output at least one second light beam for querying the Rydberg state of the gas. The first light beam and the at least one second light beam are guided within the vapor cell in a manner distributed over the planar extension of the vapor cell.

### TECHNICAL FIELD

The present disclosure relates to the testing of test objects. In particular, embodiments of the present disclosure relate to a test device, a test system and a method for testing a test object.

### BACKGROUND

The testing of test objects in manufacturing and quality assurance processes is an essential part of modern production. In many cases, in particular in systems with a high number of signal channels, conventional wired test methods prove to be insufficient. Thus, for example, base stations which are equipped with a two-dimensional antenna array for massive MIMO (massive multiple input multiple output) are difficult to test using wired measurement methods.

Conventional testing methods therefore predominantly use over-the-air (OTA) measurements. A sensor is positioned in an anechoic zone of an anechoic chamber in order to evaluate the signal emitted by the test object using a spectrum analyzer. However, the establishment of such a quiet zone often requires large chambers with considerable dimensions.

Therefore, there may be a need for improved testing of test objects.

### SUMMARY

Such a demand is satisfied by a test device, a test system and a method for testing a test object according to the independent claims. Further aspects and further developments are specified in the dependent claims, the following description and in the figures.

According to a first aspect, the present disclosure relates to a test device. The test device comprises a planar vapor cell which is filled with a gas. The vapor cell is a closed container and/or vessel in which the gas is contained. For example, the vapor cell may first be evacuated and then a material in liquid or solid form may be introduced into the evacuated vapor cell so that it evaporates due to its vapor pressure. The vapor cell may, for example, be a hollow and at least partially optically transparent container (e.g. made of quartz glass, sapphire, borosilicate glass or a mixture thereof). The gas may, for example, be the gas phase of an alkali metal such as rubidium (Rb), cesium (Cs) or sodium (Na). Since the vapor cell is a planar vapor cell, the vapor cell has a pronounced two-dimensional extension, while its extension in a third spatial direction is significantly smaller (e.g. less than 5 cm, in particular approximately 1 cm). For example, an extension of the planar vapor cell in two spatial directions perpendicular to one another may be at least five times, ten times, twenty times, fifty times or one hundred times greater than its extension in a further spatial direction extending perpendicular thereto.

Furthermore, the test device comprises a first light source configured to output a first light beam for exciting the gas to a Rydberg state. The first light source comprises at least one emitter such as, for instance, a laser and optionally further optical elements such as, for instance, beam forming optics (e.g. comprising at least one of lenses, mirrors, diffraction gratings or polarizers) or beam guiding optics (e.g. comprising at least one of fiber optics, mirror arrangements or optical waveguides). The first light beam may, for example, be coherent, monochromatic light (such as laser light), the wavelength and intensity of which are set such that the required energy for exciting the gas to the Rydberg state is provided. The Rydberg state is a state of an atom in which an electron reaches a highly excited level and is thus far away from the core. Atoms of the gas in the Rydberg state located in the vapor cell are distinguished by a high electrical sensitivity, which means that they react sensitively to electromagnetic fields—in particular to radio-frequency fields (RF fields). The wavelength of the first light beam may, for example, be tuned to a specific Rydberg shell, which determines whether an RF field with a specific frequency interacts with the gas in the Rydberg state.

Furthermore, the test device comprises a second light source configured to output at least one second light beam for querying the Rydberg state of the gas. The second light source may be constructed analogously to the first light source. The second light source may generate a single or multiple second light beams. The at least one second light beam may, for example, be coherent, monochromatic light (such as laser light), the wavelength and intensity of which are set such that the at least one second light beam acts selectively with one or more predetermined transitions of the gas in the Rydberg state. For example, the wavelength of the at least one second light beam may be set such that the at least one second light beam is resonant with a transition between the Rydberg state and another energy level of the gas. When the gas in the vapor cell is acted upon from the outside by a test object (e.g. in the form of electromagnetic radiation emitted by the test object), the energy levels of the atoms of the gas in the Rydberg state are shifted or split (Stark effect or Autler-Townes effect). This leads to a change in the absorption properties of the gas. The absorption of the at least one second light beam by the gas changes accordingly. In other words: the transmission of the at least one second light beam through the vapor cell depends on the Rydberg state of the gas, which in turn depends on the interaction of the test object with gas. In other words: as a result of the interaction of the emitted electromagnetic radiation (in particular of an RF field) of the test object with the excited Rydberg atoms of the gas, the light transmission of the at least one second light beam changes, which may be used as a signal for the presence and strength of the RF field.

The first light beam and the at least one second light beam are guided within the vapor cell in a manner distributed over the planar extension of the vapor cell. The first light beam and the at least one second light beam are thus not only guided at points or along a single line, but are distributed over a large area of the vapor cell. Both the first and the second light beam are thus guided through the vapor cell such that substantially the entire area of the vapor cell is illuminated.

Since the first light beam and the at least one second light beam thereby cover multiple positions and/or areas within the vapor cell, a planar, not only a point-by-point, measurement of interactions of the gas in the Rydberg state with the emitted electromagnetic radiation (in particular of an RF field) of the test object is made possible. The planar design of the vapor cell makes it possible to investigate large-area electromagnetic fields. In addition, the planar design of the vapor cell makes it possible to design the test device in a compact format.

The test device according to the first aspect makes it possible to detect electromagnetic fields of a test object over a large area and at the same time without the need for complex mechanical scanning. In particular, if the large planar side of the vapor cell, which extends over the two spatial directions perpendicular to one another, faces the test object and thus offers a large detection area for its emitted electromagnetic radiation. This reduces the test duration and enables, for example, the testing of modern communication systems, such as base stations with many antenna elements, more efficiently and precisely. If, for example, a base station with a two-dimensional antenna array for massive MIMO, which transmits signals over many channels, is to be tested, the radiation may be detected in a planar manner by the test device according to the first aspect. The use of a planar vapor cell with gas atoms in the Rydberg state makes it possible to detect electromagnetic radiation such as RF fields in a sensitive and comprehensive manner, which facilitates and improves the testing, in particular in manufacturing environments.

According to some embodiments of the present disclosure, the planar vapor cell is cuboidal. In other words: the geometric shape of the vapor cell is a rectangular parallelepiped. As already noted above, the extension of the vapor cell in two spatial directions perpendicular to one another (e.g. X and Y direction) is significantly greater (e.g. at least five times, ten times, twenty times, fifty times or one hundred times) than its extension in a further spatial direction extending perpendicular thereto (e.g. Z direction). Due to the cuboidal geometry, the vapor cell in these embodiments thus has a pronounced plate shape. The planar extension enables a uniform and broad distribution of the first light beam and of the at least one second light beam within the vapor cell. A further advantage of the cuboidal geometry is the possibility of efficiently integrating the vapor cell into test structures in which a planar measurement is desired. In particular in the case of OTA measurements of modern base stations with two-dimensional antenna arrays for massive MIMO, it is thus possible to capture a large area simultaneously or successively. The planar geometry of the vapor cell makes it possible for the entire antenna arrays to be covered without the test object or the vapor cell having to be moved.

In some embodiments of the present disclosure, the first light beam and the at least one second light beam are guided in antiparallel within the vapor cell. In other words: the first light beam and the at least one second light beam are guided through the vapor cell such that they have opposite propagation directions, but run largely along the same or parallel lines through the vapor cell. The first light beam is used for exciting the gas to a Rydberg state, while the at least one second light beam is used for querying this excited state. The antiparallel guidance ensures that the interaction between the light beams and the excited atoms may take place over as large an area as possible and in an efficient manner. In particular, the antiparallel guidance ensures that the at least one second light beam impinges on the same area of the gas which is excited by the first light beam. This is advantageous for a precise detection of the Rydberg state.

According to some embodiments of the present disclosure, the test device further comprises a plurality of mirrors (i.e. N≥2 mirrors). At least a part of the plurality of mirrors is arranged along a spatial direction on two opposite sides of the vapor cell and is configured to reflect the first light beam back and forth between the two opposite sides over the extension of the vapor cell along the spatial direction. In these embodiments, the first light beam is guided within the vapor cell with the aid of at least a part of the plurality of mirrors. The first light beam is reflected by the mirrors such that it runs back and forth multiple times between the two opposite sides of the vapor cell and is thus guided in a manner distributed over the planar extension of the vapor cell. Since the first light beam thus passes through the vapor cell multiple times, the interaction between the first light beam and the gas located in the vapor cell is increased, which contributes to an effective excitation of the gas to the Rydberg state. Even with limited installation space of the vapor cell, a large effective interaction length may thus be achieved, which increases the measurement sensitivity. A mirror may be understood here as any optical device which deflects light beams by reflection. In particular, it may be a smooth, reflective surface (e.g. aluminum, silver or dielectric coatings which are applied to a substrate such as glass or quartz) which reflects back a large part of the incident light. The spatial direction along which at least a part of the plurality of mirrors is arranged is a spatial direction in which the vapor cell extends in a planar manner, in particular a spatial direction which is identical or parallel to one of the two above-described spatial directions perpendicular to one another, in which the vapor cell extends in a planar manner. For example, the spatial direction along which at least a part of the plurality of mirrors is arranged may be the width direction of the vapor cell. Accordingly, the two opposite sides between which the first light beam is reflected back and forth may be the upper side and the lower side of the vapor cell. Alternatively, if the spatial direction along which at least a part of the plurality of mirrors is arranged is the height direction of the vapor cell, the two opposite sides between which the first light beam is reflected back and forth may be the left side and the right side of the vapor cell.

In some embodiments of the present disclosure, the plurality of mirrors is configured to be transparent for the at least one second light beam. The plurality of mirrors in these embodiments thus allows the at least one second light beam to pass through completely or at least partially (e.g. more than 80%, 85%, 90%, 95% or 99%). The at least one second light beam is thus substantially not reflected by the plurality of mirrors. For example, the plurality of mirrors may be configured as semitransparent mirrors, which enable both reflection and transmission, or as grating mirrors or dichroic mirrors, which are selectively transparent for specific wavelengths or polarizations. Grating mirrors or dichroic mirrors may be used in particular when the at least one second light beam has a different wavelength than the first light beam. The transparency of the plurality of mirrors for the at least second light beam enables independent guidance of the light beams and thus an improved signal flow. The first light beam is reflected by the mirrors and distributed within the vapor cell in order to convert the gas to the Rydberg state. At the same time, the at least one second light beam, which is used for querying the Rydberg state, may pass unhindered through the plurality of mirrors and thus be detected without impairment. The planar distribution of the first light beam by the mirrors enables large-area excitation of the gas to the Rydberg state, while the at least one second light beam functions as an independent querying mechanism, which may pass freely through the mirrors.

According to some embodiments of the present disclosure, the plurality of mirrors is configured to guide the first light beam along the spatial direction successively over different subareas of the planar extension of the vapor cell. The subareas are sections of the planar extension of the vapor cell, through which the first light beam is selectively guided. The subareas may have identical or different sizes and do not necessarily have to be uniformly distributed along the spatial direction. The subareas may be, for example, vertically extending sections (i.e. from the upper side to the lower side) of the vapor cell, which follow one another along the width direction of the vapor cell. In these embodiments, the light beam is not distributed simultaneously over the entire surface of the vapor cell, but successively over different subareas. Thus, the measurement may take place sequentially in specific subareas of the vapor cell. A high spatial resolution may be achieved by the targeted guidance of the first light beam over different subareas, which is advantageous in particular in the measurement of high-frequency electromagnetic fields. Dynamic measurements may also be enabled by this targeted guidance. By the first light beam being guided sequentially over different subareas, time-dependent changes in electromagnetic fields of a test object may be detected. For example, temporally and spatially resolved measurements of the sometimes highly complex signal patterns of base stations with two-dimensional antenna arrays may thus be carried out. The sequential guidance of the first light beam along the spatial direction over different subareas of the planar extension of the vapor cell may take place in a variety of ways. Two exemplary embodiments will be described in more detail below.

In some embodiments of the present disclosure, individual ones of the mirrors are arranged and/or configured to be pivotable, rotatable, tiltable or displaceable, such that the first light beam received by the first light source is successively irradiated into the vapor cell and reflected back and forth by different mirrors of the plurality of mirrors, such that the first light beam is accordingly guided successively over different subareas of the planar extension of the vapor cell. The test device may have, for example, one or more drives which are configured to move one or more mirrors of the plurality of mirrors, such that the first light beam is sequentially irradiated into the vapor cell (and reflected back and forth) by different mirrors of the plurality of mirrors and is thus guided successively over the different subareas of the planar extension of the vapor cell.

In alternative embodiments of the present disclosure, the first light source is coupled to a linear drive. The linear drive is configured to move the first light source along the spatial direction (e.g. a width direction of the vapor cell), as a result of which (such that) the first light beam is sequentially irradiated into the vapor cell by different mirrors of the plurality of mirrors and is thus guided successively over the different subareas of the planar extension of the vapor cell. As a result of the linear movement of the first light source along the spatial direction along which the mirrors are also arranged, the first light beam emitted by the first light source successively impinges on different mirrors and is thus sequentially irradiated into the vapor cell by different mirrors of the plurality of mirrors. Accordingly, the first light beam is guided successively over the different subareas of the planar extension of the vapor cell. The linear drive may, for example, be a stepper motor or a linear motor.

According to embodiments, the movement of the first light source with a linear drive may also be combined in combination with the mirrors arranged and/or configured to be pivotable, rotatable, tiltable or displaceable, in order to guide the first light beam sequentially over the different subareas of the planar extension of the vapor cell one after the other.

According to some embodiments of the present disclosure, a first part of the plurality of mirrors is arranged along the spatial direction on the two opposite sides of the vapor cell and is configured to reflect the first light beam back and forth between the two opposite sides over the extension of the vapor cell along the spatial direction in a first operating mode (and/or in a first operating phase) of the test device. A second part of the plurality of mirrors is arranged along a further spatial direction, which is perpendicular to the spatial direction, on two opposite further sides of the vapor cell and is configured to reflect the first light beam back and forth between the two opposite further sides over the extension of the vapor cell along the further spatial direction in a second operating mode (and/or in a second operating phase) of the test device. A two-dimensional scanning of the vapor cell is thus enabled. For example, temporally and spatially resolved measurements of the sometimes highly complex signal patterns of base stations with two-dimensional antenna arrays may thus be carried out. In particular, it is also possible to switch dynamically between the two operating modes (and/or operating phases). For this purpose, the test device may comprise, for example, a further pivotable, rotatable or tiltable mirror, which guides (and/or directs) the first light beam onto the first part of the plurality of mirrors in the first operating mode and onto the second part of the plurality of mirrors in the second operating mode. This allows fast adaptation to different measurement requirements and increases the efficiency of the measurement. The spatial direction and the further spatial direction along which the plurality of mirrors is arranged are spatial directions in which the vapor cell extends in a planar manner, in particular spatial directions which are identical or parallel to the two above-described spatial directions perpendicular to one another, in which the vapor cell extends in a planar manner. For example, the spatial direction along which the first part of the plurality of mirrors is arranged may be the width direction of the vapor cell and the further spatial direction along which the second part of the plurality of mirrors is arranged may be the height direction of the vapor cell. Accordingly, the two opposite sides between which the first light beam is reflected back and forth in the first operating mode may be the upper side and the lower side of the vapor cell and the two opposite further sides between which the first light beam is reflected back and forth in the second operating mode may be the left side and the right side of the vapor cell.

In some embodiments of the present disclosure, the plurality of mirrors is arranged within the vapor cell. In these embodiments, the mirrors are thus located inside the closed volume of the vapor cell. In these embodiments, the first light beam emitted by the first light source first enters the vapor cell (e.g. because the vapor cell is embodied as an optically transparent container or comprises an optical window for the passage of the first light beam) and is subsequently guided over the planar extension of the vapor cell by the mirrors without leaving the housing of the vapor cell. This reduces losses due to scattering or absorption, which could occur if the light beam had to leave the vapor cell and enter again. A high degree of reflection and precise guidance of the first light beam is thus ensured by the mirror arrangement within the vapor cell.

In alternative embodiments of the present disclosure, the plurality of mirrors is arranged outside the vapor cell. In these embodiments, the mirrors are thus located outside the closed volume of the vapor cell. This offers greater flexibility in the arrangement and adjustment of the mirrors. Since the mirrors are not fixedly mounted within the vapor cell, they may be easily adjusted, replaced or repositioned in order to optimally guide the first light beam. This flexibility is advantageous if the test device is to be tuned to different measurement tasks or light sources. In contrast to the internal arrangement of the mirrors, the external arrangement allows faster adaptation of the optical system, which increases the efficiency of the test device. The external arrangement of the mirrors is also advantageous for maintenance and cleaning. If the mirrors are arranged outside the vapor cell, they may be maintained or cleaned without opening or disturbing the vapor cell. This is particularly relevant if the test device is to be regularly recalibrated or adapted for different measurement configurations. The possibility of making the mirrors accessible from the outside increases the operating time of the test device since no complex disassembly or cleaning processes are required.

According to some embodiments of the present disclosure, the test device comprises an optical waveguide instead of the mirrors. An optical waveguide may be understood here as any optical component which may transmit light over longer distances with low (e.g. minimal) loss. In particular, the optical waveguide may be one or more optical fibers (e.g. glass or plastic fibers) which guide light by means of total reflection along their core. In these embodiments, the optical waveguide is coupled to the first light source and is configured to split the first light beam into several partial beams, which are guided in a manner distributed over the extension of the vapor cell along a spatial direction. The splitting may take place in different ways. For example, the optical waveguide may be formed as a fiber bundle or as a branched line system and may be configured to split the first light beam into different fibers or branches of the line system, which each generate a partial beam. Alternatively, the optical waveguide may comprise one or more beam splitters or one or more gratings, which split the first light beam selectively into several partial beams. These partial beams are subsequently guided in a manner distributed over the extension of the vapor cell along the spatial direction. The distribution of the partial beams over the vapor cell enables homogeneous illumination of the gas over the planar extension of the vapor cell. The splitting of the light beam into several partial beams enables efficient coverage of larger areas within the vapor cell, which is advantageous in particular in the case of large-area vapor cells. The spatial direction along which the multiple partial beams are guided in a distributed manner is a spatial direction in which the vapor cell extends in a planar manner, in particular a spatial direction which is identical or parallel to one of the two above-described spatial directions perpendicular to one another, in which the vapor cell extends in a planar manner. For example, the spatial direction along which the multiple partial beams are guided in a distributed manner may be the width direction of the vapor cell. Accordingly, the partial beams may extend from the upper side to the lower side of the vapor cell or vice versa. Alternatively, if the spatial direction along which the multiple partial beams are guided in a distributed manner is the height direction of the vapor cell, the partial beams may extend from the left side to the right side of the vapor cell or vice versa.

In some embodiments of the present disclosure, the at least one optical waveguide is configured to guide the multiple partial beams along the spatial direction successively over different subareas of the planar extension of the vapor cell. In these embodiments, partial beams are not distributed simultaneously over the entire area of the vapor cell, but successively over different subareas. The subareas are as described above for the embodiments with the mirrors. A high spatial resolution may be achieved by the targeted guidance of the partial beams over different subareas, which is advantageous in particular for the measurement of high-frequency electromagnetic fields. Dynamic measurements may also be enabled by this targeted guidance. By the partial beams being guided sequentially over different subareas, time-dependent changes in electromagnetic fields of a test object may be detected. For example, temporally and spatially resolved measurements of the sometimes highly complex signal patterns of base stations with two-dimensional antenna arrays may thus be carried out. For example, the optical waveguide may be configured to split and/or introduce the first light beam successively into different fibers of a fiber bundle or different branches of a line system, in order to guide partial beams successively over different subareas of the planar extension of the vapor cell.

According to some embodiments of the present disclosure, the test device further comprises at least one photodetector configured to measure the at least one second light beam. A photodetector may be understood as any light-sensitive component configured to convert incident light beams into electrical signals. For example, the at least one photodetector may be and/or comprise a semiconductor component such as a photodiode, an avalanche photodiode, a phototransistor or a photoelectron multiplier. As described above, the at least one second light beam interacts with the gas in the vapor cell and thereby records information about the state of the gas. This information may be present in the form of changes in the light intensity, polarization or spectral composition. The photodetector permits the detection of these changes and the conversion thereof into an electrical signal which may subsequently be analyzed outside the test device.

In some embodiments of the present disclosure, a plurality of second light beams is guided in a manner distributed (and in parallel to one another) along a spatial direction over the planar extension of the vapor cell. Successive ones of the plurality of second light beams are each oriented in antiparallel. This means that adjacent second light beams each extend in opposite directions. In these embodiments, the test device further comprises a plurality of photodetectors configured to measure the plurality of second light beams. The photodetectors are arranged at least partially along the spatial direction alternately on two opposite sides of the vapor cell. The spatial direction along which the plurality of second light beams is guided is a spatial direction in which the vapor cell extends in a planar manner, in particular a spatial direction which is identical or parallel to one of the two above-described spatial directions perpendicular to one another, in which the vapor cell extends in a planar manner. For example, the spatial direction along which the plurality of second light beams is guided may be the width direction of the vapor cell. Accordingly, the two opposite sides on which the photodetectors are arranged may be the upper side and the lower side of the vapor cell. Alternatively, if the spatial direction along which the plurality of second light beams is guided is the height direction of the vapor cell, the two opposite sides on which the photodetectors are arranged may be the left side and the right side of the vapor cell. In these embodiments, one of the second light beams thus extends through the vapor cell between two adjacent photodetectors arranged on the same side of the vapor cell. The photodetectors are arranged to respectively measure one of the second light beams. The second light beams are irradiated into the vapor cell on the side of the vapor cell opposite the respective photodetector, such that the respective second light beam runs and/or is guided through the vapor cell to the photodetector. In other words: the second light beams are irradiated into the vapor cell along the spatial direction alternately on the two opposite sides of the vapor cell. For this purpose, the second light source may be arranged on the two opposite sides of the vapor cell in a manner distributed between the photodetectors. For example, an emitter of the second light source and one of the photodetectors may be respectively arranged alternately on the two opposite sides of the vapor cell, such that an emitter and a photodetector are respectively opposite one another on the two opposite sides of the vapor cell. Alternatively, a beam guiding element (e.g. an optical fiber or another optical waveguide) and one of the photodetectors may be arranged alternately on the two opposite sides of the vapor cell, such that a beam guiding element and a photodetector are respectively opposite one another on the two opposite sides of the vapor cell. The use of a plurality of second light beams and photodetectors enables a precise and spatially resolved measurement and thus improves the ability of the test device to detect complex electromagnetic fields and signal structures with high accuracy. The test device according to these embodiments is thus particularly suitable for the OTA measurement of complex antenna systems, such as those present in base stations, for example.

According to some embodiments of the present disclosure, the plurality of second light beams is guided in a manner distributed over the planar extension of the vapor cell along the spatial direction in a first operating mode (and/or in a first operating phase) of the test device. Further, a first part of the photodetectors is arranged as described above along the spatial direction alternately on the two opposite sides of the vapor cell. In these embodiments, the plurality of second light beams is guided in a manner distributed over the planar extension of the vapor cell along a further spatial direction, which is perpendicular to the spatial direction, in a second operating mode (and/or in a second operating phase) of the test device. Successive ones of the plurality of second light beams are in turn each oriented in antiparallel in the second operating mode. A second part of the plurality of photodetectors is arranged along the further spatial direction alternately on two opposite further sides of the vapor cell. Analogously to the above description, the second light source may also be arranged on the two opposite further sides of the vapor cell in a manner distributed between the photodetectors. A two-dimensional scanning of the vapor cell is thus enabled. For example, temporally and spatially resolved measurements of the sometimes highly complex signal patterns of base stations with two-dimensional antenna arrays may thus be carried out. In particular, it is also possible to switch dynamically between the two operating modes (and/or operating phases). For this purpose, the respective parts of the photodetectors may be activated and the second light beams may be irradiated into the vapor cell accordingly. The spatial direction and the further spatial direction along which the plurality of second light beams are guided in a distributed manner are spatial directions in which the vapor cell extends in a planar manner, in particular spatial directions which are identical or parallel to the two above-described spatial directions perpendicular to one another, in which the vapor cell extends in a planar manner. For example, the spatial direction along which the plurality of second light beams are guided in a distributed manner in the first operating mode may be the width direction of the vapor cell and the further spatial direction along which the plurality of second light beams are guided in a distributed manner in the second operating mode may be the height direction of the vapor cell. Accordingly, the two opposite sides on which the first part of the photodetectors is arranged may be the upper side and the lower side of the vapor cell and the two opposite further sides on which the second part of the photodetectors is arranged may be the left side and the right side of the vapor cell.

In some embodiments of the present disclosure, the test device further comprises a detector configured to detect a fluorescence emitted by the gas. As already explained above, one or more electrons of the atoms of the gas in the Rydberg state are excited to very high energy levels and are therefore located very far away from the atomic core, so that the atoms are particularly sensitive to external electromagnetic fields. When the gas in the vapor cell is acted upon from the outside by a test object (e.g. in the form of electromagnetic radiation emitted by the test object), the energy states of the atoms of the gas in the Rydberg state are influenced. This interaction may lead, inter alia, to the atoms of the gas excited to the Rydberg state falling back into lower energy levels. At this transition, photons are emitted, which may be observed as fluorescence. The fluorescence signals enable a direct measurement of the interaction between the atoms of the gas in the Rydberg state and the electromagnetic radiation of the test object. The frequency and intensity of the emitted fluorescence depend on the properties of the incident electromagnetic waves of the test object. By detecting this fluorescence, it is possible to determine properties of the incident radiation such as intensity, frequency and polarization. The detector for the detection of fluorescence permits the detection of these changes and the conversion thereof into an electrical signal which may subsequently be analyzed outside the test device. For example, the sometimes highly complex signal patterns of base stations with two-dimensional antenna arrays may thus be characterized. Detectors for the detection of fluorescence also enable a high spatial and temporal resolution, since they may detect local changes in the fluorescence intensity. The detector for the detection of fluorescence may be constructed in a variety of ways and be and/or comprise a semiconductor component such as a photoelectron multiplier, a CCD (charge-coupled device) or CMOS (complementary metal-oxide semiconductor) camera or an avalanche photodiode. The test device may comprise the detector for the detection of fluorescence in addition to the at least one photodetector or instead of the at least one photodetector.

According to some embodiments of the present disclosure, the test device further comprises an electrode arrangement with a segmented first electrode and a second electrode. The electrode arrangement is configured to generate an electric field within the vapor cell, which extends perpendicularly to the at least one second light beam and conducts charge carriers in the direction of the segmented first electrode. As already explained above, one or more electrons of the atoms of the gas in the Rydberg state are excited to very high energy levels and are therefore located very far away from the atomic core, so that the atoms are particularly sensitive to external electromagnetic fields. When the gas in the vapor cell is acted upon from the outside by a test object (e.g. in the form of electromagnetic radiation emitted by the test object), the energy states of the atoms of the gas in the Rydberg state are influenced. This interaction may lead, inter alia, to the ionization of the atoms of the gas, in which an electron is completely separated from the atomic nucleus, resulting in a positively charged ion and a free electron. These freely movable charge carriers (ions and electrons) are now present in the gas and are moved by the directed electric field of the electrode arrangement. Depending on the potential difference between the segmented first electrode and the second electrode, the electrons are accelerated to the segmented first electrode or to the second electrode. The ions are accelerated in the opposite direction. For example, the potential difference between the segmented first electrode and the second electrode is selected such that the electrons are accelerated towards the segmented first electrode (i.e., the first electrode functions as an anode). Since the first electrode is divided into multiple segments, the position, intensity and distribution of the charge carriers (e.g., the electrons) within the vapor cell may be measured in a locally resolved manner. Each segment of the electrode may function as a separate sensor which generates an electric signal when a charge carrier impinges thereon. The signals of the individual segments may subsequently be analyzed outside the test device in order to identify spatial differences in the distribution of the charge carriers. This distribution is directly related to the electromagnetic fields emitted by the test object. For example, the sometimes highly complex and dynamic field structures of base stations with two-dimensional antenna arrays may thus be investigated. Since the electric field and the at least one second light beam extend perpendicularly to one another, a two-dimensional scanning of the vapor cell is enabled. As already described above, the at least one second light beam may extend, for example, along a height direction of the vapor cell and the electric field may accordingly extend along a width direction of the vapor cell.

The segmented electrode also permits the detection of charge carriers perpendicularly to their extent (e.g. in the width direction of the vapor cell if the electrode is arranged along the height direction of the vapor cell). If the electromagnetic radiation emitted by the test object is pulsed, the electromagnetic radiation varies in a time-dependent manner, such that additional information about the direction perpendicular to the extent direction of the segmented electrode may be obtained by a temporal resolution of the measurement signals of the segmented electrode. In other words: if the electromagnetic radiation of the test object is present in temporally delimited pulses, the measurement with the electrode arrangement may be configured such that the temporal changes in the signals of the individual segments of the first electrode permit conclusions to be drawn about the spatial distribution of the electromagnetic radiation in the direction perpendicular to the direction of extension of the segmented electrode.

In some embodiments of the present disclosure, the test device further comprises a high-frequency source configured to generate a high-frequency reference field within the vapor cell. The high-frequency reference field is an electromagnetic field with frequencies in the range from microwaves to millimeter waves (i.e. a few GHz to over 100 GHz). The high-frequency source may comprise, for example, a high-frequency generator and a horn antenna in order to radiate a high-frequency signal generated by the high-frequency generator into the vapor cell, whereby the high-frequency reference field is generated within the vapor cell. The high-frequency reference field enables phase measurements of the electromagnetic radiation emitted by the test object. The high-frequency reference field serves as a reference point. When the electromagnetic radiation of the test object and the high-frequency reference field act simultaneously on the atoms of the gas in the Rydberg state within the vapor cell, these atoms may act as a receiving antenna which receives both components and superimposes them on one another. The superimposition produces an interfering signal, the properties of which depend on the phase position of both components. This superimposition leads to the electrons behaving differently in the excited state, depending on whether the electromagnetic radiation of the test object and the high-frequency reference field interfere constructively or destructively. This influences the generation of charge carriers (electrons and ions) within the vapor cell. The phase measurement takes place by detecting the charge carriers generated by the interfering components. This may take place in many ways. The interference influences the Rydberg state of the atoms of the gas. Changes in the Rydberg state may lead to changes in the emitted fluorescence. These changes may be measured with the above-described detector for the detection of fluorescence. The fluorescence intensity depends on the phase position of the interfering signals. Alternatively, the generated charge carriers may be measured by means of the segmented first electrode of the above-described electrode arrangement. A comparison with the electromagnetic radiation of the test object may be carried out by targeted modulation of the high-frequency reference field. For example, in the case of pulsed reference fields, the phase information may be extracted by analyzing the delay between the pulses in the signals of the segmented electrode.

In alternative embodiments of the present disclosure, at least one of the first light source or the at least one second light source is configured to modulate the first light beam and/or the at least one second light beam at a high frequency. In this case, the intensity, frequency or phase of the respective light beam is modulated with a specific high frequency. Analogously to the above-described, this frequency is in the range from microwaves to millimeter waves. The respective modulated light beam has a defined modulation frequency which is used as a reference signal for the phase measurement. The light beam modulation is an alternative to the above-described generation of the high-frequency reference field. If the modulated light beam interacts with the atoms of the gas in the Rydberg state, the modulation effect is transferred to the excitation of the atoms in the Rydberg state. This means that the interaction with the electromagnetic radiation of the test object is influenced by the modulation. If the modulation is pulsed, a temporally resolved measurement may be carried out analogously to the above-described. The influence of the electromagnetic radiation of the test object on the atoms in the Rydberg state may be precisely detected by the precise knowledge of the modulation frequency and phase. This enables phase differences between the electromagnetic radiation of the test object and the modulated light beam to be measured. Due to the modulation of the respective light source itself, no additional high-frequency source is required. Analogously to the above-described, the phase measurement may take place e.g. by measuring the emitted fluorescence or alternatively by measuring the generated charge carriers by means of the segmented first electrode of the above-described electrode arrangement.

According to some embodiments of the present disclosure, the test system further comprises a control circuit configured to control the first light source and the at least one second light source. The light sources may be arranged outside the vapor cell, so that the generated light beams are coupled into the vapor cell. The control circuit may be configured accordingly for modulation, power control and synchronization of the first and second light sources. Optionally, the control circuit may further be configured to process the measurement signals of the at least one photodetector, the detector for the detection of fluorescence and/or the segmented electrode. For example, the control circuit may be configured to receive, amplify, digitize and/or further process (e.g. filter) the measurement signals. The control circuit may be located in a separate housing which is connected to the vapor cell and the associated optical components via cable connections or optical waveguides. This allows a flexible arrangement of the control circuit in order to minimize electromagnetic interference by electronic components and to facilitate maintenance or adaptation work. The external arrangement of the control circuit also allows it to be easily replaced or upgraded if required, without requiring changes to the actual test device.

In some embodiments of the present disclosure, the test device further comprises a beamstop configured to absorb the first light beam. For example, the beamstop may be arranged outside the vapor cell in order to absorb the first light beam after it has been guided through the vapor cell. The beamstop is arranged such that the first light beam impinges on the beamstop after it has been guided through the vapor cell. Just like the first light source, the beamstop may also be coupled to a linear drive which is configured to move the beamstop along the spatial direction. Accordingly, the first light beam may be absorbed at different points along the spatial direction (in particular after any mirrors of the plurality of mirrors) in order to adjust the end of the respective subarea over which the first light beam is guided. The movement of the beamstop may in particular be synchronized with the movement of the first light source along the spatial direction.

According to a second aspect, the present disclosure relates to a test system. The test system comprises an absorber chamber (anechoic chamber) configured to receive a test object. The test system further comprises a test device according to the first aspect of the present disclosure for measuring electromagnetic radiation emitted by the test object. At least the vapor cell of the test device is arranged in the absorber chamber. Optionally, further elements of the test device such as one or more photodetectors, mirrors or parts of the second light source may be arranged in the absorber chamber. The absorber chamber is configured to (largely) absorb or shield electromagnetic radiation penetrating from outside the chamber. For this purpose, the absorber chamber may comprise absorber materials attached to the walls, ceilings and/or floors of the absorber chamber. Reflections and interference from the outside may thus be minimized. This enables a precise and unadulterated measurement of the radiation of the test object by the test device. A high measurement accuracy and reproducible results may thus be achieved. The vapor cell of the test device is oriented in the absorber chamber and/or the test object is oriented in the absorber chamber such that the large planar extension of the vapor cell extends perpendicularly to the beam direction of the test object.

The test device according to the first aspect makes it possible to carry out measurements in the near field directly next to the radiation source of the test object (e.g. an antenna array) without the need for a measurement in a so-called quiet zone of the absorber chamber. Compared to conventional measurement systems, this enables the use of significantly smaller absorber chambers, which leads to a significant reduction in size and costs of the construction. In addition, the test device offers an inherently frequency-selective detection without the need for additional, bulky filters. An exceptionally large frequency range may likewise be covered without the need to replace measurement probes. Compared to conventional arrays of near-field probes, the test device also enables a very fine spatial resolution in the field detection. Furthermore, the test object is influenced less by the test device (lower loading effect) than by conventional measurement systems. These advantages make the test system a particularly efficient and versatile solution for the characterization of test objects in absorber chambers.

In some embodiments of the present disclosure, the absorber chamber is configured to completely receive the test object. This means that the test object may be placed completely within the interior of the absorber chamber without parts of the test object remaining outside the chamber. The test object is thus completely surrounded by the absorber chamber. This ensures that all the electromagnetic radiation emitted by the test object may be detected within the absorber chamber without external interference or reflections outside the absorber chamber falsifying the measurement. This enables a precise and reproducible measurement of the electromagnetic signals of the test object. Moreover, the signal-to-noise ratio is significantly improved by the complete shielding from external interference sources. In these embodiments, the absorber chamber likewise functions as a defined measurement environment which minimizes any reflections of the emitted signals by its internal absorber materials. This is particularly advantageous if the test object is tested in the near-field measurement, since the emitted radiation may be influenced very quickly by the environment. Since the test system is able to carry out near-field measurements directly next to the test object, the complete reception of the test object enables these measurements to be carried out in a shielded environment without the typical challenge of having to create a large quiet zone. Moreover, the complete reception of the test object in the absorber chamber ensures that no electromagnetic radiation may escape from the absorber chamber. This not only has the advantage that the measurement is not impaired by external radiation, but also that the test object itself does not unintentionally cause electromagnetic interference in its environment. This is particularly advantageous when it comes to powerful transmitting units, such as those frequently used in modern communication systems. Furthermore, the complete reception of the test object in the absorber chamber enables measurements to be carried out over a very large frequency range without having to take external influences into account.

According to some embodiments of the present disclosure, the absorber chamber is configured to enable the test object to be introduced into the absorber chamber parallel to the planar extension of the vapor cell. By introducing the test object into the absorber chamber parallel to the planar extension of the vapor cell, it is ensured that the test object may be optimally positioned with respect to the measuring device. For example, the absorber chamber may have corresponding (e.g. closable) openings on one or both lateral sides through which the test object may be introduced into the absorber chamber.

In some embodiments of the present disclosure, the absorber chamber is configured to receive a conveyor (e.g. a conveyor belt) of a production line for the test object on which the test object is transported, in order to enable the test object to be introduced into the absorber chamber by means of the conveyor. This enables the test object which is transported on the conveyor to be introduced into the absorber chamber without interruption and without manual intervention. A serial testing of multiple test objects may also be carried out. For example, the test object may be introduced into the absorber chamber on the conveyor continuously or at fixed intervals without having to be lifted, rotated or moved in another way. This is advantageous in particular in the testing of large-area or sensitive test objects since these require stable and precise positioning in order to ensure consistent and repeatable measurements. By receiving the conveyor in the absorber chamber, it is ensured that a high degree of electromagnetic shielding is ensured during the measurement process. For example, the absorber chamber may have closable openings on both lateral sides through which the conveyor extends and thus the test object may be introduced into the absorber chamber and removed again from the absorber chamber after the measurement. The openings are closed during the measurement. The closing elements may be designed in such a way that they enclose the part of the conveyor extending through the openings (e.g. corresponding recesses for the conveyor may be provided in the closing elements).

As already indicated multiple times, the test object may be, for example, a base station, in particular a base station with a two-dimensional antenna array. However, the present disclosure is not restricted to base stations. Rather, any test object which emits electromagnetic radiation may be tested. Thus, according to embodiments, the test system may also be used for testing radar systems, mobile telephones, WLAN routers or the like.

According to a third aspect, the present disclosure relates to a method for testing a test object. The method comprises introducing the test object into an absorber chamber. The method further comprises measuring electromagnetic radiation emitted by the test object in the absorber chamber by means of a test device according to the first aspect of the present disclosure. At least the vapor cell of the test device is arranged in the absorber chamber. With the method, the above-described advantages and effects may be achieved in an analogous manner.

### BRIEF DESCRIPTION OF THE FIGURES

Some examples of devices and/or methods will be described in the following by way of example only and with reference to the accompanying figures, in which:

FIG. 1 shows a first embodiment of a test device;

FIG. 2 shows a second embodiment of a test device;

FIG. 3 shows a third embodiment of a test device;

FIG. 4 shows a fourth embodiment of a test device;

FIG. 5 shows an embodiment of a test system; and

FIG. 6 shows a flow diagram of a method for testing a test object.

### DESCRIPTION

Some examples are now described in more detail with reference to the enclosed figures. However, other possible examples are not limited to the features of these embodiments described in detail. These may include modifications of the features as well as equivalents and alternatives to the features. Furthermore, the terminology used herein to describe certain examples should not be restrictive of further possible examples.

Throughout the description of the figures, same or similar reference numerals refer to same or similar elements and/or features, which may, in each case, be identical or implemented in a modified form while providing the same or a similar function. The thickness of lines, layers and/or areas in the figures may also be exaggerated for clarification.

When two elements A and B are combined using an ‘or’, this is to be understood as disclosing all possible combinations, i.e., only A, only B as well as A and B, unless expressly defined otherwise in the individual case. As an alternative wording for the same combinations, “at least one of A or B” or “A and/or B” may be used. This applies equivalently to combinations of more than two elements.

If a singular form, such as “a,” “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

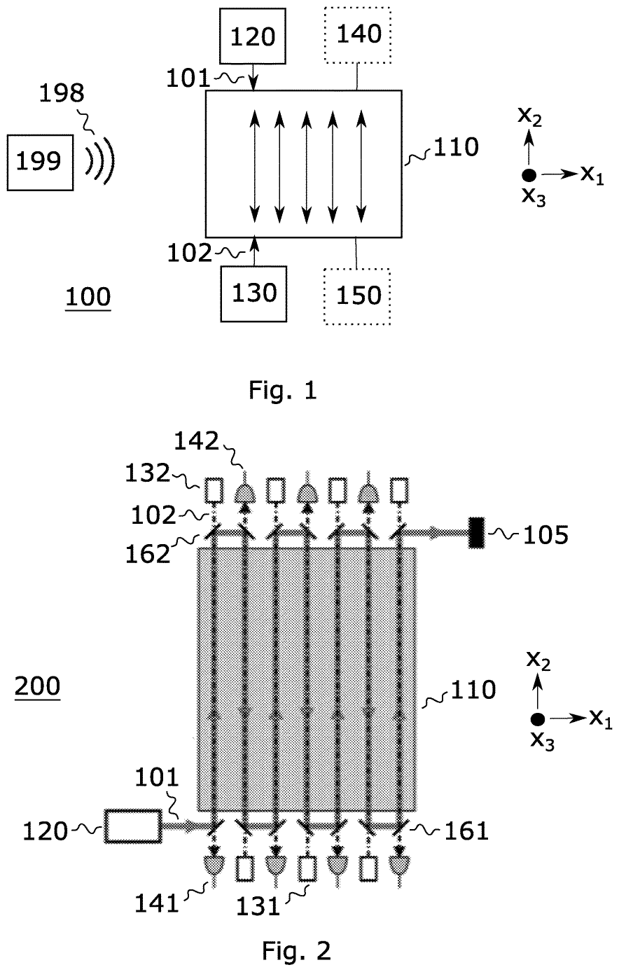

FIG. 1 schematically shows a first embodiment of a test device 100 for testing a test object 199 which emits electromagnetic radiation 198 such as an RF field.

The test device 100 comprises a planar vapor cell 110 which is filled with a gas. The vapor cell 110 has an extension in the spatial directions x₁ and x₂ perpendicular to one another (width and height direction of the vapor cell 110) which is significantly greater (e.g. at least five times, ten times, twenty times, fifty times or one hundred times) than its extension of the spatial direction x₃ (depth direction of the vapor cell 110) which extends out of the drawing plane and is thus perpendicular to the two spatial directions x₁ and x₂. In the example of FIG. 1, the vapor cell 110 is cuboidal. The gas is the gas phase of an alkali metal such as Rb, Cs or Na.

Furthermore, the test device 100 comprises a first light source 120 configured to output a first light beam 101 (e.g. a laser beam) for exciting the gas to a Rydberg state.

Furthermore, the test device 100 comprises a second light source 130 configured to output at least one second light beam 102 (e.g. one or more laser beams) for querying the Rydberg state of the gas.

The first light beam 101 and the at least one second light beam 102 are guided in antiparallel within the vapor cell 110 in a manner distributed over the planar extension of the vapor cell 110. As indicated in FIG. 1 by the arrows in the vapor cell 110, the first light beam 101 and the at least one second light beam 102 are thus not only guided at points or along a single line, but are distributed over a large area of the vapor cell 110. Both the first and the at least one second light beam 101, 102 are thus guided through the vapor cell 110 such that substantially the entire area of the vapor cell 110 is illuminated.

Atoms of the gas in the Rydberg state located in the vapor cell 110 are distinguished by a high electrical sensitivity, which means that they react sensitively to the electromagnetic radiation 198 of the test object. Since the first light beam 101 and the at least one second light beam 102 cover multiple positions and/or areas within the vapor cell 110 due to the distributed guidance over the planar extension of the vapor cell 110, a planar, not only a point-by-point, measurement of interactions of the gas in the Rydberg state with the emitted electromagnetic radiation 198 of the test object 199 is made possible. The emitted electromagnetic radiation 198 of the test object 199 may thus be detected over a large area and at the same time without the need for complex mechanical scanning. The antiparallel guidance ensures that the at least one second light beam 102 impinges on the same areas of the gas which are excited by the first light beam 101. This enables a precise detection of the Rydberg state.

If the test object 199 is, for example, a base station with a two-dimensional antenna array for massive MIMO, the signals transmitted via the many channels of the base station may be detected in a planar manner. Accordingly, the test device 100 may be used, for example, for a sensitive and comprehensive OTA testing of base stations in manufacturing environments.

As indicated in FIG. 1, the test device 100 may optionally further comprise a photodetector 140 configured to measure the at least one second light beam 102. As described above, the at least one second light beam 102 interacts with the gas in the vapor cell 110 and thereby records information about the state of the gas. This information may be present in the form of changes in the light intensity, polarization or spectral composition. The at least one photodetector 140 permits the detection of these changes and their conversion into an electrical signal which may subsequently be analyzed outside the test device 100.

Alternatively or additionally, the test device 100 may comprise a detector 150 configured to detect a fluorescence emitted by the gas in the vapor cell 110. The energy states of the atoms of the gas in the Rydberg state are influenced by the electromagnetic radiation 198 of the test object. This interaction may lead, inter alia, to the atoms of the gas excited to the Rydberg state falling back into lower energy levels. At this transition, photons are emitted, which may be observed as fluorescence. The fluorescence signals enable a direct measurement of the interaction between the atoms of the gas in the Rydberg state and the electromagnetic radiation 198 of the test object 199. The frequency and intensity of the emitted fluorescence depend on the properties of the incident electromagnetic radiation 198 of the test object 199. By detecting this fluorescence, it is possible to determine properties of the incident electromagnetic radiation 198 of the test object 199 such as intensity, frequency and polarization. The detector 150 permits the detection of these changes and their conversion into an electrical signal which may subsequently be analyzed outside the test device 100.

FIG. 2 schematically shows a second embodiment of a test device 200 for testing a test object which emits electromagnetic radiation such as an RF field.

Analogously to the test device 100, the test device 200 also comprises a planar vapor cell 110 which is filled with a gas, as well as a first light source 120 configured to output a first light beam 101 (e.g. a laser beam) for exciting the gas to a Rydberg state.

Further, the test device 200 comprises a plurality of mirrors which are arranged along the spatial direction x₁ on two opposite sides of the vapor cell 110. A first part 161 of the plurality of mirrors is arranged on the lower side of the vapor cell 110. A second part 162 of the plurality of mirrors is arranged on the upper side of the vapor cell 110. In the example of FIG. 2, the plurality of mirrors 161, 162 is arranged outside the vapor cell 110. In alternative embodiments, the plurality of mirrors 161, 162 may also be arranged within the vapor cell 110.

As illustrated in FIG. 2, the plurality of mirrors 161, 162 is configured and/or arranged to reflect the first light beam 101 back and forth between the two opposite sides (upper side and lower side) of the vapor cell 110 over the extension of the vapor cell 110 along the spatial direction x₁.

The first light beam 101 is reflected by the mirrors 161 and 162 such that it runs back and forth multiple times between the two opposite sides of the vapor cell 110 and is thus guided in a manner distributed over the planar extension of the vapor cell 110. Since the first light beam 101 thus passes through the vapor cell 110 multiple times, the interaction between the first light beam 101 and the gas located in the vapor cell is increased, which leads to an effective excitation of the gas to the Rydberg state.

In FIG. 2, seven mirrors are respectively arranged on the lower side and the upper side of the vapor cell. The number of mirrors in FIG. 2 has been selected for illustrative purposes only. More or fewer mirrors may also be used, depending on the desired number of reflections of the first light beam between the two opposite sides of the vapor cell 110.

The test device 200 furthermore comprises a beam stopper 105 arranged outside the vapor cell 110 and configured to absorb the first light beam 110 after it has been guided through the vapor cell 110.

In the embodiment of FIG. 2, the second light source is arranged in a distributed manner on the two opposite sides of the vapor cell. First partial elements 131 of the second light source on the lower side of the vapor cell 110 and second partial elements 132 of the second light source on the upper side of the vapor cell 110 are schematically shown. The partial elements 131 and 132 are arranged along the spatial direction x₁ alternately on the two opposite sides of the vapor cell 110. The partial elements 131 and 132 may, for example, be emitters (e.g. laser emitters) of the second light source, which respectively emit a second light beam 102 (e.g. a laser beam). Alternatively, the second light source may have only a single emitter and the partial elements 131 and 132 may be beam guiding elements (e.g. optical fibers or other optical waveguides) correspondingly coupled to the emitter, which respectively emit a second light beam 102 (e.g. a laser beam). The second light beams 102 emitted by the partial elements 131 and 132 extend in antiparallel to the first light beam 101 between the upper side and the lower side of the vapor cell. In other words: the partial elements 131 and 132 and the plurality of mirrors 161 and 162 are arranged such that the first light beam 101 and the plurality of second light beams 102 are guided in an overlapping but antiparallel manner through the vapor cell.

In FIG. 2, three and/or four partial elements of the second light source are arranged on the lower side and the upper side of the vapor cell. The number of partial elements in FIG. 2 has been selected for illustrative purposes only. More or fewer partial elements may also be used, depending on the desired number of second light beams.

In addition, the test device 200 comprises a plurality of photodetectors configured and/or arranged to measure the plurality of second light beams 102. A first part 141 of the plurality of photodetectors is arranged on the lower side of the vapor cell 110. A second part 142 of the plurality of photodetectors is arranged on the upper side of the vapor cell 110. The photodetectors 141 and 142 are thus arranged along the spatial direction x₁ alternately on two opposite sides of the vapor cell 110. A partial element 131 and/or 132 of the second light source and one of the photodetectors 141 and/or 142 is respectively arranged alternately on the opposite sides of the vapor cell 110, such that a partial element of the second light source and a photodetector are respectively opposite one another on the two opposite sides of the vapor cell 110. Thus, one of the second light beams 102 is respectively measured by one of the photodetectors 141 and 142.

The plurality of mirrors 161, 162 is configured to be transparent for the second light beams 102, such that they may be detected without impairment.

The use of multiple second light beams 102 and photodetectors 141, 142 enables a precise and spatially resolved measurement and thus improves the ability of the test device 200 to detect complex electromagnetic fields and signal structures with high accuracy. The test device 200 is thus particularly suitable for the OTA measurement of complex antenna systems, such as those present in base stations, for example.

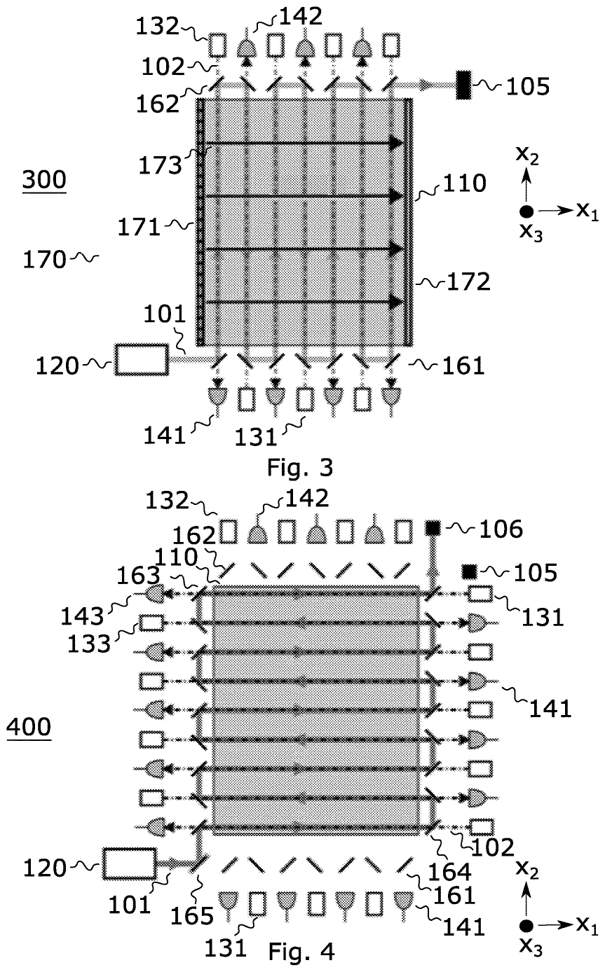

FIG. 3 schematically shows a third embodiment of a test device 300 for testing a test object which emits electromagnetic radiation such as an RF field. The test device 300 is based on the above-described test device 200, so that only the differences between the two test devices 200 and 300 will be described below.

Compared to the test device 200, the test device 300 additionally comprises an electrode arrangement 170 with a segmented first electrode 171 and a second electrode 172. The electrode arrangement 170 is configured to generate an electric field within the vapor cell 100. The electric field is indicated by the arrows 173 in FIG. 3.

The two electrodes 171 and 172 are arranged along the spatial direction x₂ and thus along the height direction of the vapor cell 110. Accordingly, the electric field 173 extends along the spatial direction x₁ and thus perpendicularly to the second light beams 102.

Charge carriers present in the gas are conducted to the segmented first electrode 171 or to the second electrode 172 depending on their electric charge. As already explained above, one or more electrons of the atoms of the gas in the Rydberg state are excited to very high energy levels and are therefore located very far away from the atomic nucleus, so that the atoms are particularly sensitive to the electromagnetic radiation of the test object. The energy states of the atoms of the gas in the Rydberg state are influenced by the electromagnetic radiation of the test object, which may lead, inter alia, to the ionization of the atoms of the gas. The resulting freely movable charge carriers (ions and electrons) are moved to the electrodes 171 and 172 by the directed electric field 173 of the electrode arrangement 170. In the example of FIG. 3, the potential difference between the segmented first electrode 171 and the second electrode 172 has been selected such that the segmented first electrode 171 functions as an anode and the electrons are accelerated towards the segmented first electrode 171. Accordingly, the positively charged ions move to the second electrode 172 under the influence of the electric field 173.

Since the first electrode 171 is divided into multiple segments, the position, intensity and distribution of the electrons within the vapor cell 110 may be measured in a locally resolved manner. Each segment of the first electrode 171 functions as a separate sensor which generates an electric signal when a charge carrier impinges thereon. The signals of the individual segments may subsequently be analyzed outside the test device 300 in order to identify spatial differences in the distribution of the electrons.

This distribution is directly related to the field structure of the electromagnetic radiation of the test object. For example, highly complex and dynamic field structures of base stations with two-dimensional antenna arrays may thus be investigated. Since the electric field 173 and the second light beams 102 extend perpendicularly to one another, a two-dimensional scanning of the vapor cell 110 is enabled.

The segmented first electrode 171 further permits the detection of electrons in the spatial direction x₁, i.e. in the width direction of the vapor cell 110, if the electromagnetic radiation of the test object is pulsed. In the case of pulsed radiation, the electromagnetic radiation varies in a time-dependent manner, such that additional information about the spatial direction x₁ may be obtained by a temporal resolution of the measurement signals of the segmented first electrode 171.

FIG. 4 schematically shows a fourth embodiment of a test device 400 for testing a test object which emits electromagnetic radiation such as an RF field. The test device 400 is based on the above-described test device 200, so that only the differences between the two test devices 200 and 400 will be described below.

Compared to the test device 200, the plurality of mirrors in the test device 400 is distributed over all four sides of the vapor cell 110. A first part 161 of the plurality of mirrors is arranged on the lower side of the vapor cell 110. A second part 162 of the plurality of mirrors is arranged on the upper side of the vapor cell 110. In addition, a third part 163 of the plurality of mirrors is arranged on the left side of the vapor cell 110 and a fourth part 164 of the plurality of mirrors is arranged on the right side of the vapor cell 110. The first part 161 and the second part 162 of the plurality of mirrors are thus arranged along the spatial direction x₁ on two opposite sides of the vapor cell 110. The third part 163 and the fourth part 164 of the plurality of mirrors are accordingly arranged along the spatial direction x₂ on two opposite further sides of the vapor cell 110.

In a first operating mode and/or a first operating phase of the test device 400, the first part 161 and the second part 162 of the plurality of mirrors—as described above in connection with FIG. 2—are configured and/or arranged to reflect the first light beam 101 back and forth between the two opposite sides (upper side and lower side) of the vapor cell 110 over the extension of the vapor cell 110 along the spatial direction x₁. This is not explicitly illustrated in FIG. 4.

A second operating mode and/or a second operating phase of the test device 400 is explicitly illustrated in FIG. 4, in which the third part 163 and the fourth part 164 of the plurality of mirrors are configured and/or arranged to reflect the first light beam 101 back and forth between the two opposite further sides (left side and right side) of the vapor cell 110 over the extension of the vapor cell 110 along the spatial direction x2.

The first light beam 101 is reflected by the mirrors 163 and 164 in the second operating mode such that it runs back and forth multiple times between the two opposite further sides of the vapor cell 110 and is thus guided in a manner distributed over the planar extension of the vapor cell 110. Since the first light beam 101 thus passes through the vapor cell 110 multiple times, the interaction between the first light beam 101 and the gas located in the vapor cell is increased, which leads to an effective excitation of the gas to the Rydberg state.

In the embodiment of FIG. 4, the second light source is arranged in a manner distributed on all four sides of the vapor cell 110. In addition to the first partial elements 131 of the second light source on the lower side of the vapor cell 110 and second partial elements 132 of the second light source on the upper side of the vapor cell 110, third partial elements 133 of the second light source on the left side of the vapor cell 110 and fourth partial elements 134 of the second light source on the right side of the vapor cell 110 are shown. The third and fourth partial elements 133 and 134 are formed analogously to the first and second partial elements 131 and 132. The partial elements 133 and 134 are arranged along the spatial direction x₂ alternately on the two opposite further sides of the vapor cell 110. The second light beams 102 emitted by the partial elements 133 and 134 in the second operating mode extend in antiparallel to the first light beam 101 between the left side and the right side of the vapor cell 110. In other words: the partial elements 133 and 134 and the plurality of mirrors 163 and 164 are arranged such that the first light beam 101 and the plurality of second light beams 102 are guided in an overlapping but antiparallel manner through the vapor cell 110.

In addition to the first part 141 of the plurality of photodetectors arranged on the lower side of the vapor cell 110 and the second part 142 of the plurality of photodetectors arranged on the upper side of the vapor cell 110, a third part 143 of the plurality of photodetectors on the left side of the vapor cell 110 and a fourth part 144 of the plurality of photodetectors on the right side of the vapor cell 110 are shown. The third and fourth photodetectors 143 and 144 are formed analogously to the first and second photodetectors 141 and 142. The photodetectors 143 and 144 are arranged along the spatial direction x₂ alternately on the two opposite further sides of the vapor cell 110, such that a partial element 133 and/or 134 of the second light source and a photodetector 144 and/or 143 are respectively opposite one another on the two opposite further sides of the vapor cell 110. Thus, in the second operating mode, one of the second light beams 102 emitted by the partial elements 133 and 134 is respectively measured by one of the photodetectors 143 and 144.

The plurality of mirrors 161, 162, 163 and 164 is configured to be transparent for the second light beams 102, such that they may be detected without impairment in the respective operating mode.

The further mirrors, photodetectors and partial elements of the second light source enable a two-dimensional scanning of the vapor cell 110. For example, the electromagnetic radiation of the test object may thus be measured in a temporally and spatially resolved manner.

The test device 400 may switch dynamically between the two operating modes (and/or operating phases). For this purpose, the test device 400 comprises a pivotable, rotatable or tiltable mirror 165, which guides (and/or directs) the first light beam 101 onto the first part 161 and the second part 162 of the plurality of mirrors in the first operating mode and onto the third part 163 and the fourth part 164 of the plurality of mirrors in the second operating mode. This allows fast adaptation to different measurement requirements and increases the efficiency of the measurement.

In FIG. 4, seven mirrors are respectively arranged on the lower side and the upper side of the vapor cell 110 and nine mirrors are respectively arranged on the left side and the right side of the vapor cell 100. The number of mirrors in FIG. 4 has been selected for illustrative purposes only. More or fewer mirrors may also be used, depending on the desired number of reflections of the first light beam between the two opposite sides and/or the two opposite further sides of the vapor cell 110. This applies analogously to the number of partial elements of the second light source and the number of photodetectors on the sides of the vapor cell 110—these may be selected as desired, in particular depending on the desired number of second light beams.

The test device 400 comprises a further beamstop 106 arranged outside the vapor cell 110 and configured to absorb the first light beam 110 in the second operating mode after it has been guided through the vapor cell 110. The beamstop 105 absorbs the first light beam in the first operating mode as described above in connection with FIG. 2.

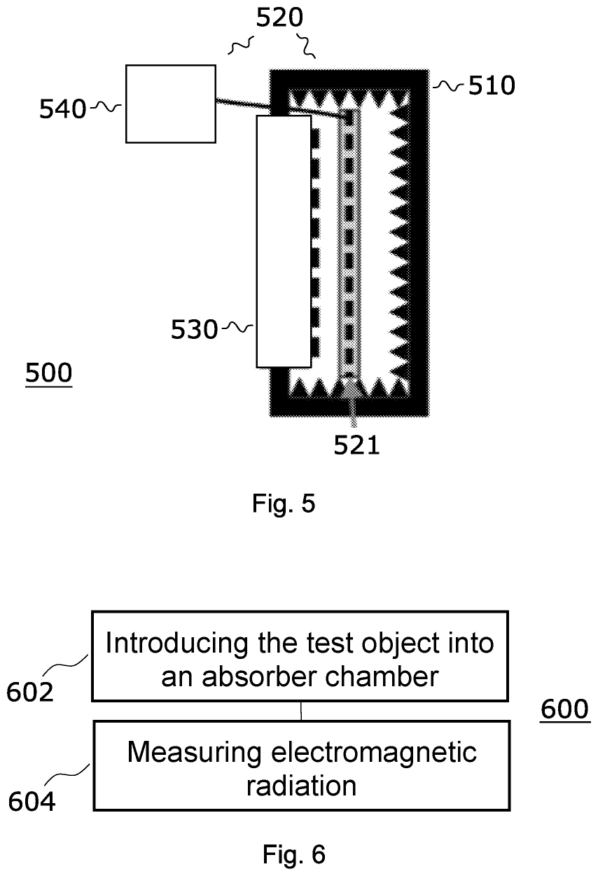

FIG. 5 furthermore shows a top view of a test system 500. The test system 510 comprises an absorber chamber 510 with absorber material on the walls, which is configured to receive a test object 530. The test system 500 further comprises a test device 520 according to the present disclosure arranged in the absorber chamber 510 for measuring electromagnetic radiation emitted by the test object 520. For example, the test object 530 may be a base station, in particular a base station with a two-dimensional antenna array for massive MIMO.

The vapor cell 521 of the test device 520 is oriented in the absorber chamber 510 such that the large planar extension of the vapor cell 521 extends perpendicularly to the beam direction of the test object 530. In other words: the test object 530 is arranged frontally in front of the large planar extension of the vapor cell 521.

The upper side of the absorber chamber 510 is not illustrated in FIG. 5.

The test device 520 according to the present disclosure enables measurements in the near field to be carried out directly next to the radiation source of the test object 530 (e.g. an antenna array) without the need for a measurement in the quiet zone of the absorber chamber 510. Compared to conventional measurement systems, the absorber chamber 510 may therefore be embodied to be significantly smaller. In addition, the test device 520 according to the present disclosure offers an inherently frequency-selective detection without the need for additional, bulky filters. An exceptionally large frequency range may likewise be covered without the need to replace measurement probes. Compared to conventional arrays of near-field probes, the test device 520 according to the present disclosure also enables a very fine spatial resolution in the field detection. Furthermore, the test object 530 is influenced less by the test device 520 according to the present disclosure than by conventional measurement systems.

Further shown in FIG. 5 is a separate housing 540 outside the absorber chamber 510, which houses the emitters (e.g. laser emitters) of the first second light sources of the test device and a control circuit for the first and second light sources. The housing is connected to the vapor cell 521 and the associated optical components of the test device 520 via cable connections and/or optical waveguides.

In order to summarize the above-described aspects for testing test objects once again, FIG. 6 shows another flow diagram of a method 600 for testing a test object. The method 600 comprises introducing 602 the test object into an absorber chamber. The method 600 further comprises measuring 604 electromagnetic radiation emitted by the test object by means of a test device according to the present disclosure. At least the vapor cell of the test device is arranged in the absorber chamber.

Analogously to the above-described, the method 600 enables an improved measurement of the electromagnetic radiation emitted by the test object.

More details and aspects of the method 600 are described above in connection with further embodiments (e.g. FIG. 1 to FIG. 5). The method 600 may include one or more optional features according to the further embodiments.

The aspects and features described in relation to a particular one of the previous examples may also be combined with one or more of the further examples to replace an identical or similar feature of that further example or to additionally introduce the feature into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes or -operations.

If some aspects in the previous sections have been described in relation to a device or system, these aspects should also be understood as a description of the corresponding method. In this case, for example, a block, a device or a functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that—although in the claims a dependent claim refers to a particular combination with one or more other claims—other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A test device comprising:
a planar vapor cell which is filled with a gas;
a first light source configured to output a first light beam for exciting the gas to a Rydberg state; and
a second light source configured to output at least one second light beam for querying the Rydberg state of the gas,
wherein the first light beam and the at least one second light beam are guided within the vapor cell in a manner distributed over the planar extension of the vapor cell.

2. The test device according to claim 1, wherein the planar vapor cell is cuboidal, and wherein an extension of the planar vapor cell in two spatial directions perpendicular to one another is at least ten times greater than its extension in a further spatial direction extending perpendicular thereto.

3. The test device according to claim 1, wherein the first light beam and the at least one second light beam are guided in antiparallel within the vapor cell.

4. The test device according to claim 1, further comprising a plurality of mirrors, wherein at least a part of the plurality of mirrors is arranged along a spatial direction on two opposite sides of the vapor cell and is configured to reflect the first light beam back and forth between the two opposite sides over the extension of the vapor cell along the spatial direction.

5. The test device according to claim 4, wherein the plurality of mirrors is configured to be transparent for the at least one second light beam.

6. The test device according to claim 4, wherein the plurality of mirrors is configured to guide the first light beam along the spatial direction successively over different subareas of the planar extension of the vapor cell.

7. The test device according to claim 6, wherein the first light source is coupled to a linear drive which is configured to move the first light source along the spatial direction, as a result of which the first light beam is sequentially irradiated into the vapor cell by different mirrors of the plurality of mirrors and is thus guided successively over the different subareas of the planar extension of the vapor cell.

8. The test device according to claim 4, wherein a first part of the plurality of mirrors is arranged along the spatial direction on the two opposite sides of the vapor cell and is configured to reflect the first light beam back and forth between the two opposite sides over the extension of the vapor cell along the spatial direction in a first operating mode of the test device, and wherein a second part of the plurality of mirrors is arranged along a further spatial direction, which is perpendicular to the spatial direction, on two opposite further sides of the vapor cell and is configured to reflect the first light beam back and forth between the two opposite further sides over the extension of the vapor cell along the further spatial direction in a second operating mode of the test device.

9. The test device according to claim 4, wherein the plurality of mirrors is arranged within the vapor cell, or wherein the plurality of mirrors is arranged outside the vapor cell.

10. The test device according to claim 1, further comprising at least one optical waveguide, which is coupled to the first light source and is configured to split the first light beam into several partial beams, which are guided in a manner distributed over the extension of the vapor cell along a spatial direction.

11. The test device according to claim 1, wherein a plurality of second light beams is guided along a spatial direction in a manner distributed over the planar extension of the vapor cell, wherein successive ones of the plurality of second light beams are each oriented in antiparallel, wherein the test device further comprises a plurality of photodetectors configured to measure the plurality of second light beams, and wherein the photodetectors are arranged at least partially along the spatial direction alternately on two opposite sides of the vapor cell.

12. The test device according to claim 11, wherein the plurality of second light beams is guided in a manner distributed over the planar extension of the vapor cell along the spatial direction in a first operating mode of the test device, wherein a first part of the photodetectors is arranged along the spatial direction alternately on the two opposite sides of the vapor cell, wherein the plurality of second light beams is guided in a manner distributed over the planar extension of the vapor cell along a further spatial direction, which is perpendicular to the spatial direction, in a second operating mode of the test device, wherein successive ones of the plurality of second light beams are each oriented in antiparallel in the second operating mode, and wherein a second part of the plurality of photodetectors is arranged along the further spatial direction alternately on two opposite further sides of the vapor cell.

13. The test device according to claim 1, further comprising a detector configured to detect a fluorescence emitted by the gas.

14. The test device according to claim 1, further comprising an electrode arrangement with a segmented first electrode and a second electrode, wherein the electrode arrangement is configured to generate an electric field within the vapor cell, which extends perpendicularly to the at least one second light beam and conducts charge carriers in the direction of the segmented first electrode.

15. The test device according to claim 1, further comprising a high-frequency source configured to generate a high-frequency reference field within the vapor cell, or wherein at least one of the first light source or the second light source is configured to modulate the first light beam and/or the at least one second light beam at a high frequency.

16. A test system comprising:
an absorber chamber configured to receive a test object; and
a test device according to claim 1 for measuring electromagnetic radiation emitted by the test object, wherein at least the vapor cell of the test device is arranged in the absorber chamber.

17. The test system according to claim 16, wherein the absorber chamber is configured to completely receive the test object.

18. The test system according to claim 16, wherein the absorber chamber is configured to enable the test object to be introduced into the absorber chamber in parallel to the planar extension of the vapor cell.

19. The test system according to claim 16, wherein the absorber chamber is configured to receive a conveyor of a production line for the test object on which the test object is transported, in order to enable the test object to be introduced into the absorber chamber by means of the conveyor.

20. A method for testing a test object, comprising:
introducing the test object into an absorber chamber; and
measuring electromagnetic radiation emitted by the test object by means of a test device according to claim 1, wherein at least the vapor cell of the test device is arranged in the absorber chamber.
